(19) United States
(12) Patent Application Publication
(10) Pub. No.: US 2017/0263883 A1
(43) Pub. Date: Sep. 14, 2017

(54) Organic Light Emitting Diode Device and Array Substrate

(71) Applicant: Shenzhen China Star Optoelectronics Technology Co., Ltd., Shenzhen, Guangdong (CN)

(72) Inventor: Chao Xu, Shenzhen (CN)

(73) Assignee: Shenzhen China Star Optoelectronics Technology Co., Ltd., Shenzhen, Guangdong (CN)

(21) Appl. No.: 14/896,225

(22) PCT Filed: Oct. 12, 2015
(86) PCT No.: PCT/CN2015/091747

§ 371 Date: Dec. 4, 2015

(30) Foreign Application Priority Data
Sep. 22, 2015 (CN) 201510606333.3

(51) Int. Cl. H01L 51/52; H01L 51/50; H01L 27/32

(52) U.S. Cl. CPC H01L 51/5215; H01L 27/3244; H01L 51/5212; H01L 51/5088; H01L 51/5056; H01L 51/5012; H01L 51/5072; H01L 51/5234; H01L 2251/558

(57) ABSTRACT

An organic light emitting diode device and array substrate having the organic light emitting diode are provided. The organic light emitting diode device of the embodiment of the present invention can reduce a resistance of the transparent anode, which is used for providing holes, in a horizontal direction through setting two transparent anode layers and disposing a metal layer therebetween, and further can improve a horizontal conductivity of the transparent anode, thereby solving the problem of uneven light emission of the organic light emitting diode device due to the greater horizontal resistance of the transparent anode for improving the quality of the screen display having the array substrate.

### FIELD OF THE INVENTION

The present invention relates to display technology, and more particularly to an organic light emitting diode device and array substrate.

### BACKGROUND OF THE INVENTION

Currently, during the operation of a large area OLED (organic light emitting diode) display panel, a phenomenon of light emitting unevenly often occurs. The phenomenon is caused by a variety of reasons, the main reasons being the uneven distribution of vertical resistance and the excessively large amount of horizontal resistance. Besides, the vertical resistance is mainly determined by an energy level structure, carrier mobility, and a thickness of each layer of the device, and the horizontal resistance is mainly determined by a conductivity of a transparent electrode.

Making low resistance transparent electrodes is currently difficult. Thus, the horizontal resistance of the transparent electrode (i.e., the resistance in the horizontal direction) is relatively high. During the operation of the organic light emitting diode, when a current is applied to the edge of the transparent anode, it is difficult for the current to reach a central region of the transparent anode. Therefore, uneven light emitting of the OLED device is caused. Especially when the brightness is increased, the phenomenon of light emitting unevenly is more significant.

Thus, it is necessary to provide an organic light emitting diode device and a display panel having an array substrate consisting of the organic light emitting diode device to solve the problems of the prior art.

### SUMMARY OF THE INVENTION

The present invention provides an organic light emitting diode device and a display panel to solve the problems of uneven light emission of the OLED device in the conventional technology.

In order to solve the aforementioned drawbacks of the prior art, the present invention provides a technical solution as follows.

The embodiment of the present invention provides an organic light emitting diode device comprising:

a transparent anode utilized for being driven to output a hole;

a hole injecting layer disposed on the transparent anode for receiving the hole output by the transparent anode;

a hole transporting layer disposed on the hole injection layer for transporting the hole of the hole injecting layer to an organic light-emitting layer;

the organic light-emitting layer disposed on the hole transporting layer for receiving the hole transported by the hole transporting layer and an electron transported by an electron transmission layer, and further emitting a light in accordance with the hole and the electron;

the electron transmission layer disposed on the organic light-emitting layer for transporting an electron output by a transparent cathode to the organic light-emitting layer; and

the transparent cathode disposed on the electron transmission layer for being driven to output the electron to the electron transmission layer;

wherein the transparent anode comprises:

a first transparent anode;

a metal layer disposed on a surface of the first transparent anode and covering the surface of the first transparent anode for reducing a resistance of the transparent anode of the organic light emitting diode device in a horizontal direction;

the metal layer comprising:

a plurality of metal wires;

a second transparent anode disposed on the metal layer;

wherein the hole injecting layer is disposed on a surface of the second transparent anode, the surface of the second transparent anode is a flat surface.

In the organic light emitting diode device described above, the metal wire is made of a first metal material, the first transparent anode is made of a first transparent material, the second transparent anode is made of a second transparent material, a conductivity of the first metal material is greater than a conductivity of the first transparent material and a conductivity of the second transparent material.

In the organic light emitting diode device described above, the plurality of metal wires are interleaved for forming a plurality of metal wires grid.

In the organic light emitting diode device described above, the metal wires comprise a first metal wire extending in a first direction and a second metal wire extending in a second direction. A line width of the first metal wire is not the same as a line width of the second metal wire.

In the organic light emitting diode device described above, the metal wires comprise a first metal wire extending in a first direction and a second metal wire extending in a second direction. A thickness of the first metal wire is not the same as a thickness of the second metal wire.

The embodiment of the present invention further provides another organic light emitting diode device comprising:

a transparent anode utilized for being driven to output a hole;

a hole injecting layer disposed on the transparent anode for receiving the hole output by the transparent anode;

a hole transporting layer disposed on the hole injection layer for transporting the hole of the hole injecting layer to an organic light-emitting layer;

the organic light-emitting layer disposed on the hole transporting layer for receiving the hole transported by the hole transporting layer and an electron transported by an electron transmission layer, and further emitting a light in accordance with the hole and the electron;

the electron transmission layer disposed on the organic light-emitting layer for transporting an electron output by a transparent cathode to the organic light-emitting layer; and

the transparent cathode disposed on the electron transmission layer for being driven to output the electron to the electron transmission layer;

wherein the transparent anode comprises:

a first transparent anode;

a metal layer disposed on a surface of the first transparent anode and covering the surface of the first transparent anode completely for reducing a resistance of the transparent anode of the organic light emitting diode device in a horizontal direction; and

a second transparent anode disposed on the metal layer.

In the organic light emitting diode device described above, the metal layer comprises a plurality of metal wires.

In the organic light emitting diode device described above, the metal wire is made of a first metal material, the first transparent anode is made of a first transparent material, the second transparent anode is made of a second transparent material, a conductivity of the first metal material is greater than a conductivity of the first transparent material and a conductivity of the second transparent material.

In the organic light emitting diode device described above, the plurality of metal wires are interleaved for forming a plurality of metal wires grid.

In the organic light emitting diode device described above, the metal wires comprise a first metal wire extending in a first direction and a second metal wire extending in a second direction. A line width of the first metal wire is not the same as a line width of the second metal wire.

In the organic light emitting diode device described above, the metal wires comprise a first metal wire extending in a first direction and a second metal wire extending in a second direction. A thickness of the first metal wire is not the same as a thickness of the second metal wire.

In the organic light emitting diode device described above, the hole injecting layer is disposed on a surface of the second transparent anode, the surface of the second transparent anode is a flat surface.

The embodiment of the present invention further provides an organic light emitting diode array substrate, comprising:

a base substrate;

an organic light emitting diode device disposed on the base substrate;

a thin film transistor disposed on the base substrate for controlling light emitting of the corresponding organic light emitting diode device;

the organic light emitting diode device comprising:

a transparent anode utilized for being driven to output a hole;

a hole injecting layer disposed on the transparent anode for receiving the hole output by the transparent anode;

a hole transporting layer disposed on the hole injection layer for transporting the hole of the hole injecting layer to an organic light-emitting layer;

the organic light-emitting layer disposed on the hole transporting layer for receiving the hole transported by the hole transporting layer and an electron transported by an electron transmission layer, and further emitting a light in accordance with the hole and the electron;

the electron transmission layer disposed on the organic light-emitting layer for transporting an electron output by a transparent cathode to the organic light-emitting layer; and

the transparent cathode disposed on the electron transmission layer for being driven to output the electron to the electron transmission layer;

wherein the transparent anode comprises:

a first transparent anode;

a metal layer disposed on a surface of the first transparent anode and covering the surface of the first transparent anode completely for reducing a resistance of the transparent anode of the organic light emitting diode device in a horizontal direction; and

a second transparent anode disposed on the metal layer.

In the organic light emitting diode array substrate described above, the metal layer comprises a plurality of metal wires.

In the organic light emitting diode array substrate described above, the plurality of metal wires are interleaved for forming a plurality of metal wires grid.

In the organic light emitting diode array substrate described above, the metal wire is made of a first metal material, the first transparent anode is made of a first transparent material, the second transparent anode is made of a second transparent material, a conductivity of the first metal material is greater than a conductivity of the first transparent material and a conductivity of the second transparent material.

In the organic light emitting diode array substrate described above, the metal wires comprise a first metal wire extending in a first direction and a second metal wire extending in a second direction. A line width of the first metal wire is not the same as a line width of the second metal wire.

In the organic light emitting diode array substrate described above, the metal wires comprise a first metal wire extending in a first direction and a second metal wire extending in a second direction. A thickness of the first metal wire is not the same as a thickness of the second metal wire.

In the organic light emitting diode array substrate described above, the hole injecting layer is disposed on a surface of the second transparent anode, the surface of the second transparent anode is a flat surface.

The embodiment of the present invention provides an organic light emitting diode device and an array substrate. The organic light emitting diode device of the embodiment of the present invention can reduce a resistance of the transparent anode in a horizontal direction through setting two transparent anode layers and disposing a metal layer therebetween, and can further improve a horizontal conductivity of the transparent anode layers, thereby solving the problem of uneven light emission of the organic light emitting diode device due to the greater horizontal resistance of the transparent anode for improving the quality of the screen display.

### DESCRIPTION OF THE DRAWINGS

FIG. 1 is a structural schematic view of an organic light emitting diode device according to an embodiment of the present invention;

FIG. 2 is a structural schematic view of a metal layer according to the embodiment of the present invention;

FIG. 3 is a schematic view of a first step of a method for manufacturing the organic light emitting diode device according to the embodiment of the present invention;

FIG. 4 is a schematic view of a second step of a method or manufacturing the organic light emitting diode device according to the embodiment of the present invention; and

FIG. 5 is a schematic view of a third step of a method or manufacturing the organic light emitting diode device according to the embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, etc., are only directions by referring to the accompanying drawings, and thus the used directional terms are used to describe and understand the present invention, but the present invention is not limited thereto. Referring to the drawings of the present invention, the same symbol represents the same component.

### Embodiment 1

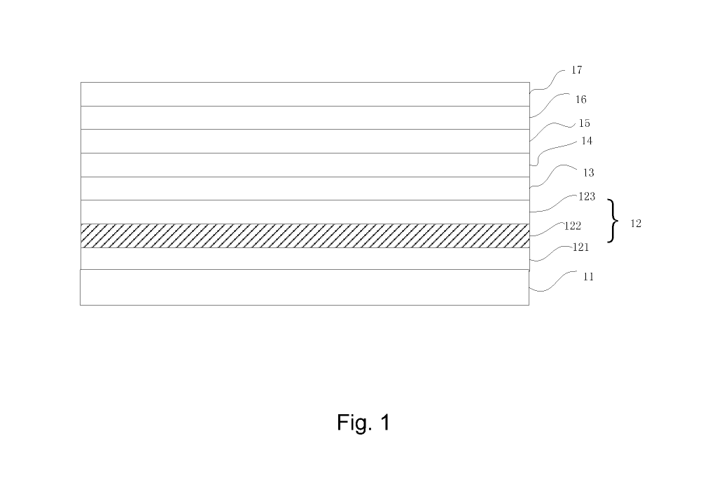

Referring to FIG. 1, the embodiment of the present invention provides an organic light emitting diode device, comprising:

a base substrate 11, which is preferably a glass substrate;

a transparent anode 12 disposed on the base substrate utilized for being driven to output a hole (alternatively referred to as a carrier), for example, when the organic light emitting diode device is in operation, the transparent anode 12 is connected to a positive electrode of a drive voltage and a transparent cathode 17 is connected to a negative electrode of the drive voltage;

a hole injecting layer 13 disposed on the transparent anode 12 for receiving the hole output by the transparent anode 12;

a hole transporting layer 14 disposed on the hole injection layer 13 for transporting the hole of the hole injecting layer to an organic light-emitting layer 15, in the embodiment, the hole transporting layer 14 can reduce an interface barrier between the transparent anode 12 and the hole transporting layer 14, also can increase an adhesion level between the transparent anode 12 and the hole transporting layer 14, and further can increase a contact area for hole injecting;

an organic light-emitting layer 15 disposed on the hole transporting layer 14 for receiving the hole transported by the hole transporting layer 14 and an electron transported by an electron transmission layer 16, and further emitting a light in accordance with the hole and the electron, specifically, when the electron and hole meet, the organic light-emitting layer releases energy in a form of photons, i.e. light-emission;

the electron transmission layer 16 disposed on the organic light-emitting layer 15 for transporting an electron output by a transparent cathode 17 to the organic light-emitting layer 15; and

the transparent cathode 17 disposed on the electron transmission layer 16 for being driven to output the electron to the electron transmission layer 16.

The transparent anode comprises:

a first transparent anode 121;

a metal layer 122 disposed on a surface of the first transparent anode 121 and covering the surface of the first transparent anode 121 completely for reducing a resistance of the transparent anode of the organic light emitting diode device in a horizontal direction (hereinafter referred to as the horizontal resistance); and

a second transparent anode 123 disposed on the metal layer 122.

The organic light emitting diode device of the embodiment of the present invention can reduce a resistance of the transparent anode in a horizontal direction through setting two transparent anode layers and disposing a metal layer therebetween, and can improve a horizontal conductivity of the transparent anode by reducing the horizontal resistance of the transparent anode, which is equivalent to connecting the transparent anode in parallel with a resistor (the resistance of the metal layer).

By reducing the horizontal resistance of the transparent anode, the current is increased compared to the conventional OLED device. During the operation of the organic light emitting diode, when a current is applied to the edge of the transparent anode, the current can thereby reach a central region of the transparent anode. Therefore, the problem of the uneven light emission of the OLED device caused by the larger horizontal resistance of the transparent anode is solved to thereby improve the quality of the screen display.

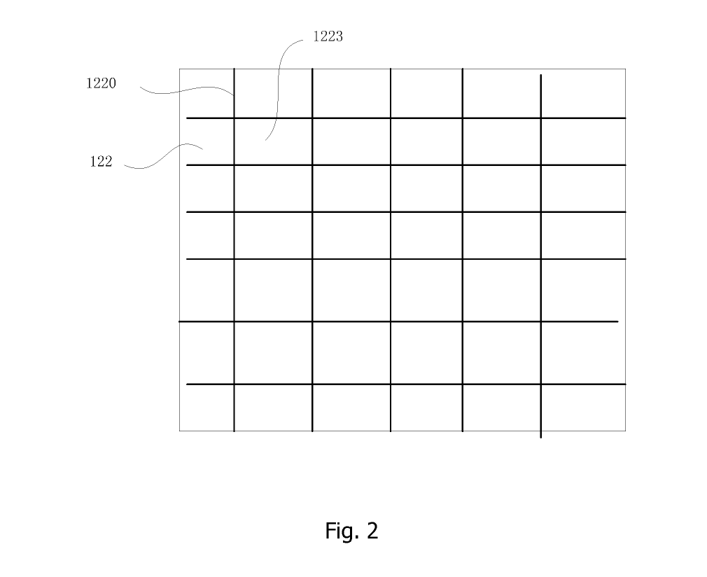

Preferably, referring to FIG. 2, the metal layer 122 comprises a plurality of metal wires 1220 in the embodiment. In the embodiment, the metal layer 122 constitutes of a plurality of metal wires 1220 for reducing costs. In addition, by using the metal wires 1220, the horizontal resistance of the transparent anode 12 can be adjusted by changing the amount of the metal wires 1220 for meeting the actual requirement, which is easy to implement.

In order to further reduce the horizontal resistance of the transparent anode 12, preferably, in the embodiment, a conductivity of a metal material of the metal layer 122 is greater than a conductivity of a material of the first transparent anode 121 and a conductivity of a material of the second transparent anode 123. Moreover, the conductivity of the material of the first transparent anode 121 and the conductivity of the material of the second transparent anode 123 can be the same or different.

Preferably, to produce more metal wires 1220 in a limited space for the horizontal resistance of the metal layer 122 to evenly distribute and reducing the resistance in the vertical direction of the organic light emitting diode device, the plurality of metal wires 1220 is interleaved for forming a plurality of metal wires grid 1223 in this embodiment. Referring to FIG. 2, two adjacent transverse metal lines 122 are interleaved for forming the metal wires grid 1223. The metal wires grid 1223 shown in FIG. 2 is a square, which can be manufactured easily. However, in other embodiments, the shape of the metal wires grid 1223 can also be triangular, hexagonal, rectangular, and the like. The shape of the metal wires grid 1223 can be manufactured based on actual demands.

Preferably, for applying in various practical situations and further for improving the light-emitting uniformity of the organic light emitting diode device, the metal wires 1220 in this embodiment comprise a first metal wire extending in a first direction, such as the transverse metal wire shown in FIG. 2, and a second metal wire extending in a second direction, such as the vertical metal wire shown in FIG. 2.

Besides, a line width of the first metal wire is not the same as a line width of the second metal wire. As shown in FIG. 2, for example, the line width of the transverse metal wire is not the same as the line width of the vertical metal wire.

In practical application, the line width of the metal wires can be set by incorporating the consideration of actual situation of the current input direction. For example, when the current input direction is the same as the first direction, the line width of the first metal wire is greater than the line width of the second metal wire for reducing the resistance of the first metal wire. Thus, the input current can reach to a central region quickly for improving the light-emitting uniformity of the organic light emitting diode device. Referring to FIG. 2, a drive current is input transversely, so that the line width of the transverse metal wire is greater than the line width of the vertical metal wire for reducing the resistance of the transverse metal wire. Therefore, the input current can reach to the central region quickly for further improving the light-emitting uniformity and efficiency of the organic light emitting diode device.

Preferably, considering the practical operation of the organic light emitting diode, the metal wires 1220 in this embodiment comprise a first metal wire extending in a first direction, such as the transverse metal wire shown in FIG. 2, and a second metal wire extending in a second direction, such as the vertical metal wire shown in FIG. 2.

A thickness of the first metal wire is not the same as a thickness of the second metal wire. As shown in FIG. 2, the thickness of the transverse metal wire is not the same as the thickness of the vertical metal wire.

In practical application, the thickness of the metal wires can be set by incorporating the consideration of the current input direction. For example, when the current input direction is the same as the first direction, the thickness of the first metal wire is greater than the thickness of the second metal wire for reducing the resistance of the first metal wire. Thus, the input current can reach to a central region quickly for improving the light-emitting uniformity of the organic light emitting diode device. Referring to FIG. 2, a drive current is input transversely, so that the thickness of the transverse metal wire is greater than the thickness of the vertical metal wire for reducing the resistance of the transverse metal wire. Therefore, the input current can reach to the central region quickly further for improving the light-emitting uniformity and efficiency of the organic light emitting diode device.

In order to ensure a good interfacial contact and energy level matching between the transparent anode 12 and the hole injection layer 13 for the hole being injected and transferred, referring to FIG. 1, the hole injecting layer 13 is disposed on a surface of the second transparent anode 123. The surface of the second transparent anode 123 is a flat surface in this embodiment. Namely, a contact surface of the second transparent anode layer 123 and the hole injection layer 13 is flat.

The embodiment of the present invention further provides a method for manufacturing the organic light emitting diode device comprising the following steps.

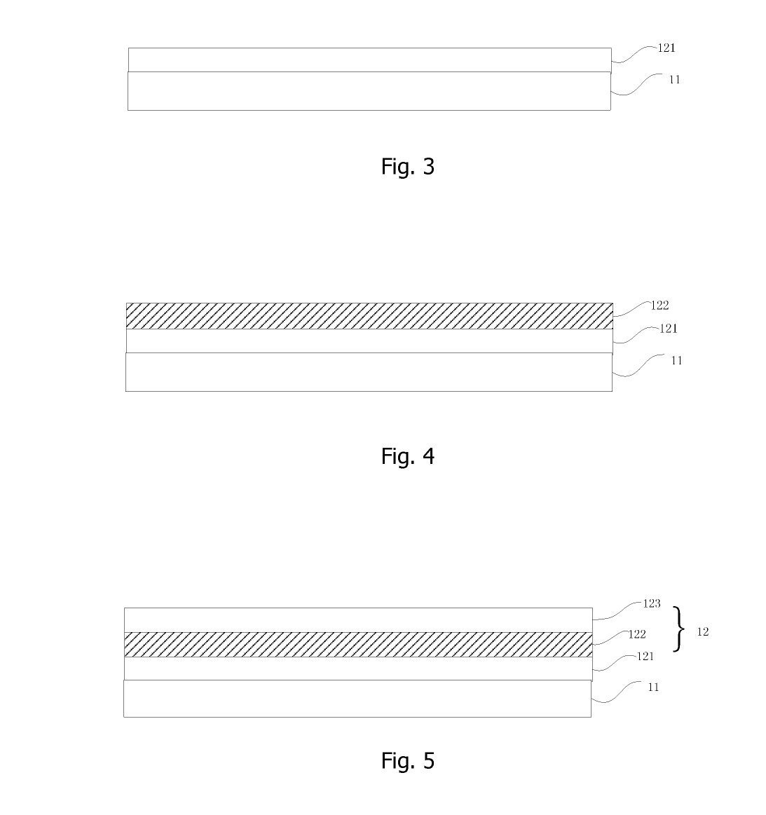

In a step S101, referring to FIG. 3, a first transparent anode layer 121 is formed on a base substrate 11.

Specifically, a first anode material is formed on the base substrate 11 (such as a glass substrate) for forming the first transparent anode layer 121 through PVD/evaporation, etc. The transparent anode material is a transparent conductive film, such as ITO/AZO (indium tin oxide/aluminum-doped zin oxide), to ensure the film and the glass has good adhesion.

In a step S102, referring to FIG. 4, a metal layer 122 is formed on the first transparent anode layer 121.

Specifically, the metal layer 122 comprises a plurality of metal wires 1220. Besides, referring to FIG. 2, the plurality of metal wires 1220 is interleaved for forming a grid from a plurality of metal wires. Moreover, the metal wires grid with high conductivity is formed on the first anode material via screen printing, etc. A material of the metal wires grid can be selected from conductive silver paste/ carbon nanotube solution and the like.

In a step S103, referring to FIG. 5, a second transparent anode layer 123 is formed on the metal layer 122.

Specifically, the anode material is coated on the metal wires 1220 once again via PVD, coating, or spin coating for forming the second transparent anode layer 123 until an upper surface of the second transparent anode layer 123 is flat.

In a step 5104, referring to FIG. 1, a hole injecting layer 13, a hole transporting layer 14, an organic light-emitting layer 15, an electron transmission layer 16, and a transparent cathode 17 are sequentially formed on the second transparent anode layer 123.

### Embodiment 2

This embodiment of the present invention provides an organic light emitting diode array substrate, comprising:

a base substrate; an organic light emitting diode device disposed on the base substrate; and

a thin film transistor disposed on the base substrate for controlling light emitting of the corresponding organic light emitting diode device.

Referring to FIG. 1, the organic light emitting diode device comprises:

a transparent anode 12 disposed on the base substrate utilized for being driven to output a hole (alternatively referred to as a carrier), for example, when the organic light emitting diode device is in operation, the transparent anode 12 is connected to a positive electrode of a drive voltage and a transparent cathode 17 is connected to a negative electrode of the drive voltage;

a hole injecting layer 13 disposed on the transparent anode 12 for receiving the hole output by the transparent anode 12;

a hole transporting layer 14 disposed on the hole injection layer 13 for transporting the hole of the hole injecting layer to an organic light-emitting layer 15, in the embodiment, the hole transporting layer 14 can reduce an interface barrier between the transparent anode 12 and the hole transporting layer 14, also can increase an adhesion level between the transparent anode 12 and the hole transporting layer 14, and further can increase a contact area for hole injecting;

an organic light-emitting layer 15 disposed on the hole transporting layer 14 for receiving the hole transported by the hole transporting layer 14 and an electron transported by an electron transmission layer 16, and further emitting a light in accordance with the hole and the electron, specifically, when the electron and hole meet, the organic light-emitting layer releases energy in a form of photons, i.e. light-emission;

the electron transmission layer 16 disposed on the organic light-emitting layer 15 for transporting an electron output by a transparent cathode 17 to the organic light-emitting layer 15; and

the transparent cathode 17 disposed on the electron transmission layer 16 for being driven to output the electron to the electron transmission layer 16.

The transparent anode comprises:

a first transparent anode 121;

a metal layer 122 disposed on a surface of the first transparent anode 121 and covering the surface of the first transparent anode 121 completely for reducing a resistance of the transparent anode of the organic light emitting diode device in a horizontal direction (hereinafter referred to the horizontal resistance); and

a second transparent anode 123 disposed on the metal layer 122.

The organic light emitting diode device of the embodiment of the present invention can reduce a resistance of the transparent anode in a horizontal direction through setting two transparent anode layers and disposing a metal layer therebetween, and can improve a horizontal conductivity of the transparent anode by reducing the horizontal resistance of the transparent anode, which is equivalent to connect the transparent anode in parallel with a resistor (the resistance of the metal layer).

By reducing the horizontal resistance of the transparent anode, the current is increased compared to the conventional OLED device. During the operation of the organic light emitting diode, when a current is applied to the edge of the transparent anode, the current can thereby reach to a central region of the transparent anode. Therefore, it solves the problem of the uneven light emission of the OLED device caused by the larger horizontal resistance of the transparent anode to thereby improve the quality of the screen display.

Preferably, referring to FIG. 2, the metal layer 122 comprises a plurality of metal wires 1220 in the embodiment. In the embodiment, the metal layer 12 constitutes of a plurality of metal wires 1220 for reducing costs. In addition, by using the metal wires 1220, the horizontal resistance of the transparent anode 12 can be adjusted by changing the amount of the metal wires 1220 for meeting the actual requirement, which is easy to implement.

The organic light emitting diode device of the embodiment of the present invention can reduce a resistance of the transparent anode in a horizontal direction through setting two transparent anode layers and disposing a metal layer therebetween, and further can improve a horizontal conductivity of the transparent anode, thereby solving the problem of uneven light emission of the organic light emitting diode device due to the greater horizontal resistance of the transparent anode for improving the quality of the screen display.

As described above, the present invention has been described with preferred embodiments thereof, and it is understood that many changes and modifications to the described embodiment can be carried out without departing from the scope and the spirit of the invention that is intended to be limited only by the appended claims.

What is claimed is:

1. An organic light emitting diode device, comprising:
a transparent anode utilized for being driven to output a hole;
a hole injecting layer disposed on the transparent anode for receiving the hole output by the transparent anode;
a hole transporting layer disposed on the hole injection layer for transporting the hole of the hole injecting layer to an organic light-emitting layer;
the organic light-emitting layer disposed on the hole transporting layer for receiving the hole transported by the hole transporting layer and an electron transported by an electron transmission layer, and further emitting a light in accordance with the hole and the electron;
the electron transmission layer disposed on the organic light-emitting layer for transporting an electron output by a transparent cathode to the organic light-emitting layer; and
the transparent cathode disposed on the electron transmission layer for being driven to output the electron to the electron transmission layer;
wherein the transparent anode comprises:
a first transparent anode;
a metal layer disposed on a surface of the first transparent anode and covering the surface of the first transparent anode for reducing a resistance of the transparent anode of the organic light emitting diode device in a horizontal direction;
the metal layer comprising:
a plurality of metal wires;
a second transparent anode disposed on the metal layer;
wherein the hole injecting layer is disposed on a surface of the second transparent anode, the surface of the second transparent anode is a flat surface.

2. The organic light emitting diode device according to claim 1, wherein the metal wire is made of a first metal material, the first transparent anode is made of a first transparent material, the second transparent anode is made of a second transparent material, a conductivity of the first metal material is greater than a conductivity of the first transparent material and a conductivity of the second transparent material.

3. The organic light emitting diode device according to claim 1, wherein the plurality of metal wires are interleaved for forming a plurality of metal wires grid.

4. The organic light emitting diode device according to claim 1, wherein the metal wires comprise:
a first metal wire extending in a first direction and a second metal wire extending in a second direction;
a line width of the first metal wire is not the same as a line width of the second metal wire.

5. The organic light emitting diode device according to claim 1, wherein the metal wires comprise:
a first metal wire extending in a first direction and a second metal wire extending in a second direction;
a thickness of the first metal wire is not the same as a thickness of the second metal wire.

6. The organic light emitting diode device according to claim 2, wherein the plurality of metal wires are interleaved for forming a plurality of metal wires grid.

7. An organic light emitting diode device, comprising:
a transparent anode utilized for being driven to output a hole;
a hole injecting layer disposed on the transparent anode for receiving the hole output by the transparent anode;
a hole transporting layer disposed on the hole injection layer for transporting the hole of the hole injecting layer to an organic light-emitting layer;
the organic light-emitting layer disposed on the hole transporting layer for receiving the hole transported by the hole transporting layer and an electron transported by an electron transmission layer, and further emitting a light in accordance with the hole and the electron;
the electron transmission layer disposed on the organic light-emitting layer for transporting an electron output by a transparent cathode to the organic light-emitting layer; and
the transparent cathode disposed on the electron transmission layer for being driven to output the electron to the electron transmission layer;
wherein the transparent anode comprises:
a first transparent anode;
a metal layer disposed on a surface of the first transparent anode and covering the surface of the first transparent anode completely for reducing a resistance of the transparent anode of the organic light emitting diode device in a horizontal direction; and
a second transparent anode disposed on the metal layer.

8. The organic light emitting diode device according to claim 7, wherein the metal layer comprises a plurality of metal wires.

9. The organic light emitting diode device according to claim 8, wherein the metal wire is made of a first metal material, the first transparent anode is made of a first transparent material, the second transparent anode is made of a second transparent material, a conductivity of the first metal material is greater than a conductivity of the first transparent material and a conductivity of the second transparent material.

10. The organic light emitting diode device according to claim 8, wherein the plurality of metal wires are interleaved for forming a plurality of metal wires grid.

11. The organic light emitting diode device according to claim 8, wherein the metal wires comprise:
a first metal wire extending in a first direction and a second metal wire extending in a second direction;
a line width of the first metal wire is not the same as a line width of the second metal wire.

12. The organic light emitting diode device according to claim 8, wherein the metal wires comprise:
a first metal wire extending in a first direction and a second metal wire extending in a second direction;
a thickness of the first metal wire is not the same as a thickness of the second metal wire.

13. The organic light emitting diode device according to claim 8, wherein the hole injecting layer is disposed on a surface of the second transparent anode, the surface of the second transparent anode is a flat surface.

14. An organic light emitting diode array substrate, comprising:
a base substrate;
an organic light emitting diode device disposed on the base substrate;
a thin film transistor disposed on the base substrate for controlling light emitting of the corresponding organic light emitting diode device;
the organic light emitting diode device comprising:
a transparent anode utilized for being driven to output a hole;
a hole injecting layer disposed on the transparent anode for receiving the hole output by the transparent anode;
a hole transporting layer disposed on the hole injection layer for transporting the hole of the hole injecting layer to an organic light-emitting layer;
the organic light-emitting layer disposed on the hole transporting layer for receiving the hole transported by the hole transporting layer and an electron transported by an electron transmission layer, and further emitting a light in accordance with the hole and the electron;
the electron transmission layer disposed on the organic light-emitting layer for transporting an electron output by a transparent cathode to the organic light-emitting layer; and
the transparent cathode disposed on the electron transmission layer for being driven to output the electron to the electron transmission layer;
wherein the transparent anode comprises:
a first transparent anode;
a metal layer disposed on a surface of the first transparent anode and covering the surface of the first transparent anode completely for reducing a resistance of the transparent anode of the organic light emitting diode device in a horizontal direction; and
a second transparent anode disposed on the metal layer.

15. The organic light emitting diode array substrate according to claim 14, wherein the metal layer comprises a plurality of metal wires.

16. The organic light emitting diode array substrate according to claim 15, wherein the plurality of metal wires are interleaved for forming a plurality of metal wires grid.

17. The organic light emitting diode array substrate according to claim 15, wherein the metal wire is made of a first metal material, the first transparent anode is made of a first transparent material, the second transparent anode is made of a second transparent material, a conductivity of the first metal material is greater than a conductivity of the first transparent material and a conductivity of the second transparent material.

18. The organic light emitting diode array substrate according to claim 15, wherein the metal wires comprise:
a first metal wire extending in a first direction and a second metal wire extending in a second direction;
a line width of the first metal wire is not the same as a line width of the second metal wire.

19. The organic light emitting diode array substrate according to claim 15, wherein the metal wires comprise:
a first metal wire extending in a first direction and a second metal wire extending in a second direction;
a thickness of the first metal wire is not the same as a thickness of the second metal wire.

20. The organic light emitting diode array substrate according to claim 15, wherein the hole injecting layer is disposed on a surface of the second transparent anode, the surface of the second transparent anode is a flat surface.
